(19) United States
(12) Patent Application Publication
(10) Pub. No.: US 2008/0251809 A1
(43) Pub. Date: Oct. 16, 2008

(54) Light-Emitting Diode

(75) Inventors: Ronald M. Wolf, Eindhoven (NL); Michel Paul Barbara Van Bruggen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/569,702

(22) PCT Filed: May 25, 2005
(86) PCT No.: PCT/IB05/51708

§ 371 Date: Nov. 28, 2006

(30) Foreign Application Priority Data
Jun. 1, 2004 (EP) 04102423.3

(51) Int. Cl. H01L 33/00

(52) U.S. Cl. 257/103; 438/22; 257/E33.003

(57) ABSTRACT

Light-emitting diode (LED) comprising a translucent substrate of α-Al₂O₃ or SiC and a first layer of a light-emitting semiconductor material grown on a first side of said substrate, a first electrode and a second electrode, wherein said substrate is polycrystalline. The average grain size of the polycrystalline substrate is preferably of the same order as the wavelength of the light emitted by the semiconductor material during use of the LED.

Such a LED is described in JP 2002-319708. In the prior art, the semiconductor material, such as GaN or other derivatives, is grown epitaxially onto a substrate of sapphire (mono-crystalline α-Al₂O₃), which has a lattice constant relatively close to the lattice constant of the semiconductor material. Since the lattice mismatch is still large, the deposited material tends to form small (10-100 nm) high-quality domains, which are twisted and tilted with respect to one another. Large densities of dislocations accommodate the disorientation between neighboring grains. If GaN is deposited directly on sapphire at a high temperature, the dislocation density is very high and the surface morphology is rough, due to preferential growth of some grains. If a low-temperature GaN layer is deposited directly onto the substrate, followed by a high-temperature GaN layer, the low-temperature layer provides nucleation sites for the high-temperature film. The low-quality, low-temperature layer is so heavily defected that it accommodates much of the mismatch between the high-quality GaN and the substrate, resulting in better high-temperature GaN films. Such a low-temperature layer is often referred to as buffer layer.

Sapphire is used as a substrate material because it has the property of being transparent to visible light and reasonably matches the GaN lattice constant, although the lattice mismatch still amounts to more than 30% (in the a direction). A problem related to the use of sapphire is its price and the difficulty of shaping the substrate to the desired form.

According to the invention, said substrate is made of a polycrystalline material, preferably polycrystalline α-Al₂O₃ or SiC. Such polycrystalline material can be prepared in a relatively cheap way and it can be easily shaped to any desired form. Although, according to the prior art, only a mono-crystalline material was believed to provide a suitable starting point to grow the semiconductor layer, it was surprisingly found that acceptable n-type and p-type semiconductor layers would also grow on polycrystalline alumina or SiC. Additionally, the preparation process of polycrystalline α-Al₂O₃ or SiC allows a combination of other ceramic components to the substrate, for instance, ceramic lenses that can manipulate the emitted light, or ceramics, metals or cermets with a high thermal conductivity to be used as heat sinks in high-power LEDs.

Said semiconductor material is chosen from the group comprising aluminum nitride, gallium nitride, indium nitride or combinations thereof (AlGaInN).

The average grain size of the polycrystalline substrate is preferably smaller than 2 times, more preferably smaller than 1.5 times, and even more preferably smaller than 1.2 times the wavelength of the light emitted by the semiconductor material during use of the LED. The average grain size of the polycrystalline substrate is preferably smaller than 400 nm, more preferably smaller than 300 nm, and even more preferably smaller than 200 nm. Polycrystalline α-Al₂O₃ and SiC has the property of being transparent when the average grain size of the polycrystalline material is comparable to the wavelength of light, or at least when the average grain size of the polycrystalline material is smaller than approximately 200 nm.

Said first layer of light-emitting semiconductor material is preferably of the n type, whereas a second layer of light-emitting semiconductor material of the p type is preferably grown on said n-type layer. Said p-type layer preferably covers only a part of the surface of the n-type layer, and in such a configuration the first electrode can be attached to the surface of the p-type layer and the second electrode can be attached to the uncovered surface of the n-type layer. In one embodiment, the p-type layer is preferably covered with a translucent Ni—Au based layer, which may be part of the first electrode. Said Ni—Au based layer acts as a hole spreading layer and a hole injection contact with the n-type layer. Furthermore, a mirror is preferably attached to the second side of the substrate, in order to reflect the light to the front side of the LED formed by the translucent Ni—Au based layer. In another embodiment, the first electrode forms a mirror reflecting the light to the front side of the LED formed by the translucent substrate.

The invention also relates to a method of producing a light-emitting diode (LED) wherein a translucent or semi-transparent substrate is provided and a first layer of a light-emitting semiconductor material is grown on a first side of said substrate, and a first electrode and a second electrode are attached to the LED, wherein said substrate is polycrystalline.

The invention will be illustrated by means of examples of embodiments, and with reference to the Figures, wherein:

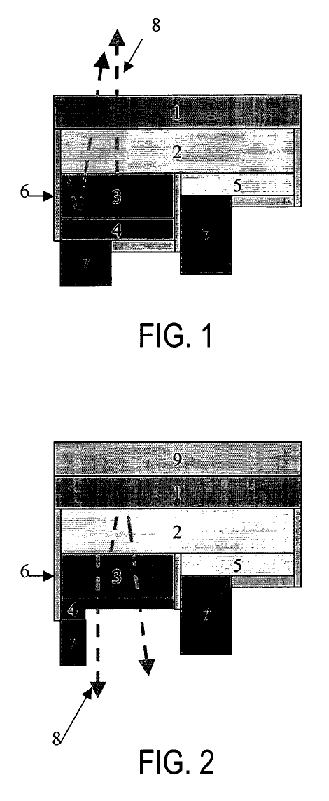

FIG. 1 is a schematic cross-section of a first embodiment of a LED; and

FIG. 2 is a schematic cross-section of a second embodiment of a LED.

Many different configurations and variations are, however, possible within the scope of the invention.

The preparation of polycrystalline alumina (α-Al₂O₃) as such is described in an article entitled “Transparent alumina: a light scattering model” (J. Am. Ceram. Soc., 86 (3) 480-486 (2003)), and also in WO 2004/007397 and WO 2004/007398, which are herein incorporated by reference. The preparation of polycrystalline SiC is also known as such, and, although the invention is illustrated by way of an example wherein polycrystalline alumina is used, polycrystalline SiC may be used in a similar manner.

A powder consisting of fine (i.e. a volume-averaged diameter equal to or below 150 nm) and well dispensable alumina particles (e.g. Taimei TM-DAR, Sumitomo AKP50) is dispersed preferably in water by deagglomeration (e.g. wet ball milling, ultrasound, etc.) and stabilization (e.g. by using HNO₃, polyacrylic acid) of the alumina particles. The alumina suspension is cast (e.g. by slipcasting, gelcasting) into molds with a predetermined shape. The shaping techniques are very versatile and allow preparation of two-dimensional and three-dimensional complex shapes.

After drying and de-molding, the porous alumina product is calcinated in oxygen to remove all undesired components (e.g. stabilizers) at a temperature substantially below the sintering temperature (preferably at least 500° C. below the sintering temperature). Subsequently, the material is sintered in a suitable sintering atmosphere (e.g. wet hydrogen, oxygen) at a temperature, such that the finally obtained density is between 97% and 98%. Depending on the process parameters, the temperature referred to will range between 1150° C. and 1300° C. After sintering, the residual porosity is removed by isothermal hot isostatic pressing at a suitably high pressure (preferably higher than 100 MPa) at a temperature equal to or slightly below the previously mentioned range of sintering temperatures, but not lower than 100° C.

The resultant product is semi-transparent and is characterized by an average grain size ranging between 0.3 and 0.8 micron, depending on the process used. However, the product is still rough due to, for example, the de-molding process. Consequently, the product needs to be polished mechanically or chemo-mechanically until diffuse scattering of light at the surface of the material has become negligible. This will correspond to an Rₐ ranging between 5 and 10 nm. Alternatively, the product may also be suspension-coated or sprayed after the calcination process, thereby rendering the laborious polishing step redundant. It may be preferable to thermally etch the resultant polished and transparent materials in order to eliminate surface artefacts induced during the polishing step. The temperatures for the thermal etching operation should range between 0° C. and 150° C. below the applied sintering temperature.

The pre-shaped, semi-transparent polycrystalline alumina substrates are subsequently used as the dies to deposit a semiconducting light-emitting material such as GaN, which material is used in light-emitting diodes (LEDs). The deposition process consists of two deposition modes, a low-temperature deposition mode (e.g. at a temperature of 500° C.) and a high-temperature deposition mode (e.g. at a temperature of 1000° C.). The material deposited at the low temperature has a poor crystalline quality and high impurity concentrations (e.g. oxygen and carbon) and it does not have the GaN device quality. Such a material is used as buffer layer. GaN films grown at 1000° C. usually have very small impurity concentrations of about 10¹⁶ cm³, even without intentional doping (n is in the low 10¹⁷ cm³ concentration range).

FIGS. 1 and 2 are cross-sections of two embodiments of a LED prepared in accordance with the above-mentioned process, wherein the LED comprises a polycrystalline alumina substrate 1 on which an n-type GaN semiconductor layer 2 is grown. A p-type GaN semiconductor layer 3 is grown on a part of the surface of the n-type layer 2. Said p-type layer is covered by a first electrode 4, whereas the remaining surface of the n-type layer 2 is covered by a second electrode 5. Both electrodes 4, 5 are made of suitable materials that provide sufficient current spreading, for instance, Ni—Au, and also allow appropriate electric contact with the n-type and p-type semiconductor materials, respectively. Where necessary, the LED is covered by an insulating layer 6. A solder bump 7 is attached to each electrode 4, 5 for connection to the terminals of an electric power supply that may be present on a sub-mount.

In the Figures, the path of the emitted light of the LED is represented by the arrows 8.

In the embodiment of FIG. 1, the first electrode 4 acts as a mirror, such that the light emitted by the p-type layer 3 is reflected by the electrode 4 towards the front side of the LED, which front side is formed by the semi-transparent substrate 1.

In the embodiment of FIG. 2, a mirror 9 is attached to the opposite side of the substrate 1, such that the light emitted by the p-type layer 3 is reflected by the mirror 9 towards the front side of the LED, which front side is formed by a thin semi-transparent layer of the first electrode 4.

1. A light-emitting diode (LED) comprising a translucent or semi-transparent substrate and a first layer of a light-emitting semiconductor material grown on a first side of said substrate, a first electrode and a second electrode, characterized in that said substrate is polycrystalline.

2. A light-emitting diode as claimed in claim 1, wherein said substrate is polycrystalline α-Al₂O₃ or polycrystalline sic.

3. A light-emitting diode as claimed in claim 1, wherein said semiconductor material is chosen from the group comprising aluminum nitride, gallium nitride, indium nitride or combinations thereof (AlGaInN).

4. A light-emitting diode as claimed in claim 1, wherein the average grain size of the polycrystalline substrate is smaller than 2 times, preferably smaller than 1.5 times, and more preferably smaller than 1.2 times the wavelength of the light emitted by the semiconductor material during use of the LED.

5. A light-emitting diode as claimed in claim 1, wherein the average grain size of the polycrystalline substrate is smaller than 400 nm, preferably smaller than 300 nm, and more preferably smaller than 200 nm.

6. A light-emitting diode as claimed in claim 1, wherein said first layer of light-emitting semiconductor material is of the n type.

7. A light-emitting diode as claimed in claim 6, wherein a second layer of light-emitting semiconductor material of the p type is grown on said n-type layer.

8. A light-emitting diode as claimed in claim 7, wherein said p-type layer covers only a part of the surface of the n-type layer.

9. A light-emitting diode as claimed in claim 8, wherein the first electrode is attached to the surface of the p-type layer and the second electrode is attached to the surface of the n-type layer.

10. A method of producing a light-emitting diode (LED), wherein a translucent or semi-transparent substrate is provided and a first layer of a light-emitting semiconductor material is grown on a first side of said substrate, and a first electrode and a second electrode are attached to the LED, characterized in that said substrate is polycrystalline.
